(19) United States
(12) Patent Application Publication
(10) Pub. No.: US 2020/0286742 A1
(43) Pub. Date: Sep. 10, 2020

(54) REMOTE PLASMA ETCH USING INKJET PRINTED ETCH MASK

(71) Applicant: Kateeva, Inc., Newark, CA (US)

(72) Inventors: Brian E. Lassiter, Berkeley, CA (US); Vera Steinmann, Menlo Park, CA (US)

(73) Assignee: Kateeva, Inc., Newark, CA (US)

(21) Appl. No.: 16/790,635

(22) Filed: Feb. 13, 2020

Related U.S. Application Data
(60) Provisional application No. 62/814,625, filed on Mar. 6, 2019.

(51) Int. Cl. H01L 21/311; H01L 21/027; H01L 51/56; H01L 51/52

(52) U.S. Cl. CPC H01L 21/31144; H01L 21/31116; H01L 51/5253; H01L 51/56; H01L 21/0271

(57) ABSTRACT

Methods of processing substrates are described herein that include depositing a patterned polymer precursor layer by inkjet printing on a substrate comprising a dielectric material, curing the precursor layer to form a patterned polymer layer, and exposing the substrate, with the patterned polymer layer, to a remote plasma etch chemistry selective to the dielectric material. These methods can be performed on display substrates, particularly OLED and/or quantum dot display substrates.

### CROSS-REFERENCE TO RELATED APPLICATIONS

This patent application claims benefit of U.S. Provisional Patent Application Ser. No. 62/814,625 filed Mar. 6, 2019, which is incorporated herein by reference.

### FIELD

Embodiments of the present invention generally relate to substrate etching processes. Specifically, methods and compositions for etching using etch masks that are applied by inkjet printing.

### BACKGROUND

Display devices are commonly used for smart phones, computer screens, and televisions. These devices typically include components having different activities. There are commonly light emitting components, electrical components, and other optical components such as color filters, polarizers, light coupling components, and the like. Many of these components are made of inorganic materials such as silicon-containing dielectric materials. Silicon oxide and silicon nitride are examples. These materials are typically formed using a CVD process, which might be a low temperature process, such as plasma-enhanced CVD, where temperature sensitive components might be compromised by high temperature. In some cases, the silicon oxide and silicon nitride layers are only formed on a portion of the panel if covering parts of the panel would be unproductive. In such cases, the inorganic materials are either formed by a CVD process using a shadow mask, or the inorganic materials are patterned after deposition.

In using a shadow mask, the desired pattern is first rendered in a mask, which can be a patterned substrate or edge frame. The inorganic material is formed as a blanket structure on the display panel. The mask substrate is positioned adjacent to the blanket inorganic material to cover a portion to be shielded from the deposition environment. The CVD deposition is then performed to deposit the inorganic material on the uncovered portion of the substrate. Material is also deposited on the shadow mask. The shadow mask process typically results in some under-flow of deposition material that reduces the precision available using the shadow mask process. As noted above, material is also deposited on the shadow mask, which changes the mask dimensions slightly with each use. Thus, the mask must be cleaned and/or replaced periodically. Also, a different mask is needed for each different pattern to be formed.

In another process, the inorganic materials can be patterned after deposition. An etch mask is applied to the inorganic material to be patterned. The etch mask is, itself, patterned by lithography, and then the pattern is transferred to the inorganic material. Current processes for patterning display panels by etching suffer from high cost and complexity, harsh processing conditions that can damage sensitive components, and use of photomasks.

There is a need in the substrate processing industry for new patterning methods.

### SUMMARY

Embodiments described herein provide a method, comprising depositing a patterned polymer precursor layer by inkjet printing on a substrate comprising a dielectric material, curing the precursor layer to form a patterned polymer layer, and exposing the substrate, with the patterned polymer layer, to a remote plasma etch chemistry selective to the dielectric material.

Other embodiments described herein provide a method, comprising forming an encapsulant layer comprising a dielectric material on a display substrate, inkjet printing a patterned polymer precursor material on the encapsulant layer, curing the precursor material to form a patterned polymer layer, and removing a portion of the dielectric material by exposing the dielectric material to a remote plasma using the patterned polymer layer as a mask.

Other embodiments described herein provide a method, comprising forming a first silicon nitride layer on an OLED display substrate, forming a polymer barrier layer over the first silicon nitride layer, forming a second silicon nitride layer over, and encapsulating, the polymer barrier layer, inkjet printing a patterned polymer precursor layer on a portion of the second silicon nitride layer to define a masked portion and an unmasked portion of the second silicon nitride layer, curing the precursor layer to form a transparent patterned polymer layer, and etching the unmasked portion of the second silicon nitride layer using a fluorine containing remote plasma and using the patterned polymer layer as an etch mask.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a flow diagram summarizing a method according to one embodiment.

FIG. 2 is a flow diagram summarizing a method according to another embodiment.

FIGS. 3A-3F are schematic cross-sectional views of a display substrate at various stages of the method of FIG. 2.

FIGS. 4A and 4B are flow diagrams summarizing two parts of a method according to yet another embodiment.

FIGS. 5A-5I are schematic cross-sectional views of a display substrate at various stages of the method of FIG. 4.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A process of inkjet printing a patterned polymer layer on a substrate and then removing uncovered portions of the substrate by exposing the substrate to a remote plasma chemistry selective to the substrate material can achieve very high etch selectivity in a convenient and efficient process. The substrate, typically comprising a dielectric material such as silicon oxide or silicon nitride, is disposed in an inkjet printer where a precursor material is deposited onto the substrate in a desired pattern. The precursor material is then solidified in a curing process to form a patterned polymer layer. The substrate, with the patterned polymer layer, is then subjected to a remote plasma process to remove uncovered portions of the dielectric material. Such processes simplify patterning of a mask layer and can eliminate high temperature processes that might damage sensitive components. In the display industry, for example, display panels often have temperature sensitive components, such as organic light-emitting diodes (OLED) and quantum dot (QD) components, which can degrade at high temperatures. Direct patterning of mask layers by inkjet printing eliminates complex masking and lithography processes associated with conventional patterning by removal, and eliminates complex shadow masking processes associated with patterned deposition.

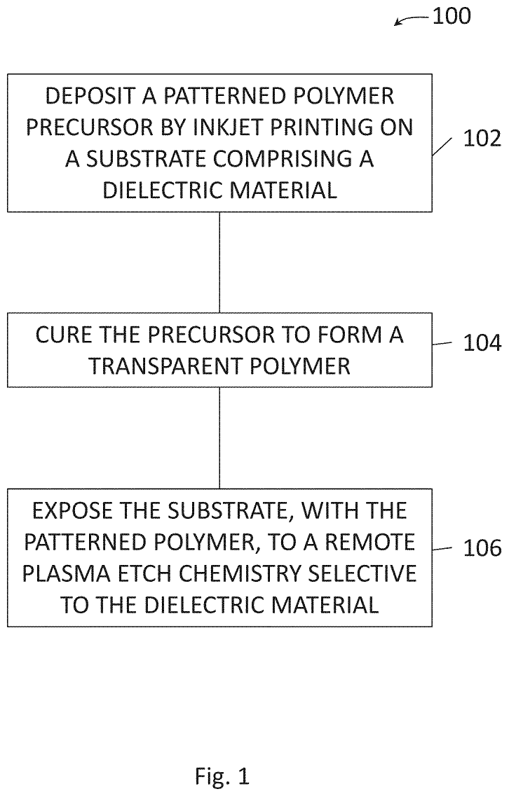

FIG. 1 is a flow diagram summarizing a method 100 according to one embodiment. The method 100 is a method of processing a substrate, which may be a display substrate such as an OLED or QD display substrate. The substrate includes an inorganic material, such as a dielectric material, for example a silicon oxide, nitride, or oxynitride material. The inorganic material can also have metal oxides such as tin oxide, zirconium oxide, aluminum oxide, titanium oxide, gallium oxide, indium-tin oxide, gallium-tin oxide, and the like. The inorganic material can also have elements such as germanium, phosphorus, boron, arsenic, selenium, and other elements that may form compound semiconductors.

At 102, a patterned polymer precursor is deposited on the substrate by inkjet printing. The precursor is a mixture that contains a polymerizable organic component, such as a monomer or prepolymer, or a plurality of polymerizable monomers or prepolymers, along with polymerization initiators and optionally solvents and optical materials such as light scattering materials. A single polymerizable precursor can be used, or a mixture of polymerizable precursors can be used. The polymerizable precursor components may include acrylic components, epoxy components, styrenic components, and siloxane components. Acrylate monomers and prepolymers can be used.

Examples of usable (meth)acrylate monomers include alkyl or aryl (meth)acrylates, such as methyl (meth)acrylate, ethyl (meth)acrylate, and benzyl (meth)acrylate (BMA); cyclic trimethylolpropane formal (meth)acrylate; alkoxylated tetrahydrofurfuryl (meth)acrylate; phenoxyalkyl (meth)acrylates, such as 2-phenoxyethyl (meth)acrylate and phenoxymethyl (meth)acrylate; 2(2-ethoxyethoxy)ethyl (meth)acrylate. Other suitable di(meth)acrylate monomers include 1,6-hexanediol diacrylate, 1,12 dodecanediol di(meth)acrylate; 1,3-butylene glycol di(meth)acrylate; di(ethylene glycol) methyl ether methacrylate; polyethylene glycol di(meth)acrylate monomers, including ethylene glycol di(meth)acrylate monomers and polyethylene glycol di(meth)acrylate monomers having a number average molecular weight in the range from, for example, about 230 g/mole to about 440 g/mole. Other mono- and di(meth)acrylate monomers that can be included in various embodiments of the ink compositions, alone or in combination, include dicyclopentenyloxyethyl acrylate (DCPOEA), isobornyl acrylate (ISOBA), dicyclopentenyloxyethyl methacrylate (DCPOEMA), isobornyl methacrylate (ISOBMA), and N-octadecyl methacrylate (OctaM). Homologs of ISOBA and ISOBMA (collectively “ISOB(M)A” homologs) in which one or more of the methyl groups on the ring is replaced by hydrogen can also be used.

Generally, useable di(meth)acrylate monomers are alkoxylated aliphatic di(meth)acrylate monomers. For example, neopentyl glycol di(meth)acrylates, including alkoxylated neopentyl glycol diacrylates, such as neopentyl glycol propoxylate di(meth)acrylate and neopentyl glycol ethoxylate di(meth)acrylate, can be used. The neopentyl glycol di(meth)acrylate monomers have molecular weight from about 200 g/mole to about 400 g/mole, such as from about 280 g/mole to about 350 g/mole, for example about 300 g/mole to about 330 g/mole. Neopentyl glycol propoxylate diacrylate can be obtained as SR9003B from Sartomer Corporation or as Aldrich-412147 from Sigma Aldrich Corporation. Meopentyl glycol diacrylate is available as Aldrich-408255 from Sigma Aldrich Corporation.

Styrenic monomers that may be used include styrene and alkylated styrenes such as methyl- and ethyl-substituted styrenes with any number of substituents, divinylbenzene and alkylates thereof, styrene or divinylbenzene dimerized or oligomerized with other olefins and diolefins such as butadiene, acrylonitrile, and acrylates. Styrene can be dimerized or oligomerized with dienes such as butadiene, pentadiene, divinylbenzene, cyclopentadiene, norbornadiene, and the like, while divinylbenzene can be dimerized or oligomerized with olefins such as ethylene, propylene, styrene, acrylic compounds such as acrylonitrile, acrylic acids, acrylates, and other familiar olefins, and/or with dienes such as butadiene, pentadiene (isoprene, piperylene), hexadiene, cyclopentadiene, and norbornadiene.

Some monomers may be crosslinking agents. The crosslinking agents are generally multifunctional vinyllic monomers having at least three reactive carbon-carbon double bonds. Multifunctional acrylates that may be used as crosslinking agents include triacrylates, tetraacrylates, tri(meth)acrylates, and tetra(meth)acrylates. Examples are pentaerythritol tetraacrylate (PET), pentaerythritol tetra(meth)acrylate, di(trimethylolpropane) tetraacrylate, and di(trimethylolpropane) tetramethacrylate.

Polymerization initiators that may be used include thermal and photoinitiators. A thermal initiator is a polymerization initiator whose highest catalytic activity is achieved under thermal stimulus. A photoinitiator is a polymerization initiator whose highest catalytic activity is achieved under radiation, usually ultraviolet radiation. Thus, while a thermal initiator may also have photocatalytic activity, the thermal initiator is most active at elevated temperature. Similarly, while a photoinitiator may be activated merely by elevated temperature, the photoinitiator will reach its highest catalytic activity under some wavelength of radiant energy, usually ultraviolet radiation.

Photoinitiators that may be used include acylphosphine oxides, α-hydroxyketones, phenylglyoxylates, and α-aminoketones. Useful photoinitiators typically absorb radiation having wavelength from about 200 nm to about 400 nm. Acylphosphine oxide examples include 2,4,6-trimethylbenzoyl-diphenylphosphine oxide (TPO) and 2,4,6-trimethylbenzoyl-diphenyl phosphinate, which may be obtained as the Irgacure® TPO initiators from BASF, for example Irgacure® 819. Thermal initiators that may be used include azo nitrile initiators such as 2,2′-azobis(2-methylpropionitrile) (AIBN), 1,1′-azobis(cyclohexanecarbonitrile), 2,2′-azobis(2-methylbutyronitrile), 2,2′-azobis(2,4-dimethylpentanenitrile), 2,2′-azobis(2,4-dimethyl-4-methoxypentanitrile), and 4,4′-azobis(4-methylcyanopentanoic acid); and peroxide initiators such as tert-amyl peroxybenzoate, tert-butyl peracetate, tert-butyl peroxybenzoate, 2,4-pentanedione peroxide, and 2,2-bis(tert-butlyperoxy)butane. Irgacure® 907 (I-907), which is 2-methyl-4′-(methylthio)-2-morpholinopropiophenone, and Irgacure® 369 (I-369), which is 2-benzyl-2-(dimethylamino)-4′-morpholinobutyrophenone, are both α-aminoketones. Irgacure® 184, which is 1-hydroxy-cyclohexyl-phenyl-ketone, is an α-hydroxyketone example. Irgacure® 754, which is oxy-phenyl-acetic acid 2-[2 oxo-2 phenyl-acetoxy-ethoxy]-ethyl ester, is a phenylglyoxylate example.

Solvents can also be included in the precursor material. For best inkjet printing results, the precursor material typically has a viscosity of 30 cp or less, such as about 5-12 cp, for example about 11 cp. A compatible solvent can be used if needed to bring viscosity into a workable range. Solvents may be selected based on solubility parameters relative to other components of the precursor material. Where an inkjet process is used to form the precursor material, the solvent should have low volatility to avoid evaporation, which can change properties of the precursor material and operation of the inkjet process. Solvents can be used where the precursor includes prepolymers with elevated viscosity. Suitable solvents include toluene, propylene glycol methyl ether acetate, butyl acetate, isobutyl acetate, isobutyl isobutyrate, acetone, isopropyl alcohol, anisole, and methyl propyl ketone.

The precursor material is deposited on the substrate by inkjet printing. Any commercial inkjet printer compatible with the materials described above can be used. One example is the YIELDjet® FLEX system available from Kateeva, Inc., of Newark, Calif. Other systems from other manufacturers can also be used. The precursor material is ejected from a dispenser at a programmed volume, velocity, and direction to arrive at the substrate in a desired location with extreme precision. The printer can thus be programmed to deposit the precursor material directly in the desired pattern without the use of other masks or patterning processes.

At 104, the precursor is cured to form a polymer. The polymer formed can be an acrylate polymer, an epoxy polymer, a styrenic polymer, a silicone polymer, or a combination thereof. The polymer can be transparent or light-blocking to any degree. The polymer has substantially the same pattern as the precursor material, with some slight shrinkage as the precursor material polymerizes, and potentially eliminates solvent. The precursor is cured by radiation, heat, or a combination thereof. For radiation processes, ultraviolet (UV) or near-UV radiation, for example radiation around 395 nm in wavelength, is used. Thermal polymerization can also be used. In either case, initiators in the precursor activate a polymerization reaction, which proceeds until the thermal or radiation stimulus is discontinued. The precursor is cured to at least about 60% conversion. This means at least about 60% of polymerizable bonds, usually carbon-carbon double bonds, in the precursor are converted to polymer bonds, usually carbon-carbon single bonds. Sometimes referred to as “curing degree,” this conversion is, in most cases, sufficient to establish a solid polymer that can be used in subsequent processing. Curing degree can be any number up to 100%, but is often 80% or higher, for example 90%.

In some cases, volatile monomers can evaporate during the curing process, especially during thermal curing processes. Solvent is also generally evaporated during or after the polymerization process. Where the precursor material includes a relatively high solvent quantity, the substrate may be subjected to a thermal process before or after curing to remove some or all of the solvent. If the substrate is subjected to thermal processing after the curing, the cured polymer prior to thermal processing may be soft, and may harden during thermal processing. If the substrate is subjected to thermal processing prior to formal curing, the inviscid liquid precursor may thicken as solvent and monomer evaporate, and as some minimal curing beings.

At 106, the substrate, with the patterned polymer, is exposed to a remote plasma etch chemistry selective to the inorganic material subjacent to the polymer. The substrate is disposed in a processing chamber of a remote plasma system, a plasma is formed in a plasma chamber of the remote plasma system, and the plasma is flowed into the processing chamber to interact with the substrate. In many cases, the substrate may include a dielectric material such as silicon oxide, nitride, or oxynitride, and the plasma may be a fluorine containing plasma.

The remote plasma contains radicals and some low energy ions that react with and remove the inorganic material without substantially affecting the organic polymer material. The polymer material thus functions as a mask defining a covered area of the substrate and an exposed area of the substrate. The plasma reaches the exposed area of the substrate, transferring the pattern of the polymer into the substrate.

For silicon-containing dielectric materials, the plasma may be formed from a plasma precursor that includes fluorine-containing materials. Usable materials include NHₓF₃₋ₓ, sulfur fluorides such as SF₆, S₃F₄, S₂F₄, SF₄, SF₃, S₂F₁₀, substituted sulfur fluorides such as SF₅(NF₂) and SF₅(Ph), where Ph is a phenyl group, and CH_{z}F_{4-z}, where x is an integer from 0 to 3, y is an integer from 0 to 6, and z is an integer from 0 to 4. Examples of such materials are NF₃, SF₆, and CF₄. Other fluorine containing species can be included such as F₂ and HF, and non-reactive species such as N₂, H₂, and Ar can also be included.

In one example, a 200×200 mm glass substrate was covered with a silicon nitride film to a thickness of 0.7 μm by PECVD. Over that, a transparent polymer layer was formed to a thickness of 2-6 mm by inkjet printing. The transparent polymer used was Kateeva FlexCap™ 1000 polymer etch mask. Some areas of the substrate were covered with polymer to a thickness of 2 μm, some to a thickness of 3 μm, some 4 μm, and some 6 μm. Three such substrates were prepared.

The substrates thus prepared were exposed to an NF₃ remote plasma in an AKT 1600 PXi plasma tool. NF₃ flow rate was 1000 sccm, pressure was 300 mTorr, and temperature was ambient. The substrates were exposed for different lengths of time—a first substrate was exposed to the remote plasma for 5 seconds, a second substrate form 240 second, and a third substrate for 999 seconds.

The substrates were removed from processing at the end of the above durations, and thickness of the silicon nitride and polymer portions was measured, with the following results:

| | SiNₓ | Polymer | Polymer | Polymer | Polymer |
|---|---|---|---|---|---|
| | Thick- | Thickness | Thickness | Thickness | Thickness |
| Etch | ness | (μm): | (μm): | (μm): | (μm): |
| Time | (μm) | 2 μm target | 3 μm target | 4 μm target | 6 μm target |
| 0 | 0.71 | 1.98 | 2.97 | 3.97 | 5.93 |
| 5 | 0.35 | 1.98 | 2.97 | 3.97 | 5.93 |
| 240 | 0 | 1.96 | 2.96 | 3.96 | 5.93 |
| 999 | 0 | 1.97 | 2.97 | 3.97 | 5.91 |

While SiNX etch rate was observed to be about 70 nm/sec on average, polymer etch rate was observed to be less than 0.04 nm/sec for an etch selectivity greater than 100. For these results, the etch selectivity was about 1,750. In many cases, no effect of the remote plasma treatment could be observed on the polymer.

The polymer can be removed following exposure to remote plasma, for example by treatment with a solvent, or in many cases the polymer can remain in the structure. Alternately, the polymer can be removed using an ashing procedure designed to remove the polymer layer without harming other components of the device. For example, a remote plasma containing oxygen can be formed in much the same way the remote plasma containing fluorine was formed, and the substrate can be exposed to the remote plasma containing oxygen. The remote plasma oxygen exposure can be performed in the same chamber where the substrate was exposed to the remote plasma containing fluorine. A gas containing substantially oxygen, such as O₂ and/or O₃ can be energized using any of the energy forms listed above for forming a remote plasma. CO, CO₂, and/or H₂O can also be included. Oxygen atoms in the remote plasma react with the carbon and hydrogen in the polymer to form volatile species, thus removing the polymer from the substrate. If the oxygen also reacts with other materials in the substrate, such as exposed metals, upon exposure to the remote plasma containing oxygen, the substrate can be exposed to a remote plasma formed from hydrogen gas to remove the oxygen and reduce the oxidized materials. In another alternative, the polymer can be removed mechanically, or chemically-mechanically, by polishing the substrate. If the polymer remains in the structure, the polymer will be transparent. In some cases it can be important to minimize the possibility of changes to the transparent polymer during subsequent processing. The transparent polymer can be cured to very high curing degree by a combination of radiation and thermal curing. For example, infrared radiation can be used to partially cure the precursor material to an intermediate curing degree until penetration of the radiation is reduced by polymerization of the precursor material. Thermal treatment can then be used to increase the curing degree to nearly 100%.

In such cases, photoinitiators and thermal initiators can both be included in the precursor mixture to facilitate curing to a high curing degree. Such curing may be beneficial in cases where minimizing change to the dimensions of the transparent polymer during subsequent processing operations is important. The high curing degree minimizes the possibility of such changes during subsequent operations.

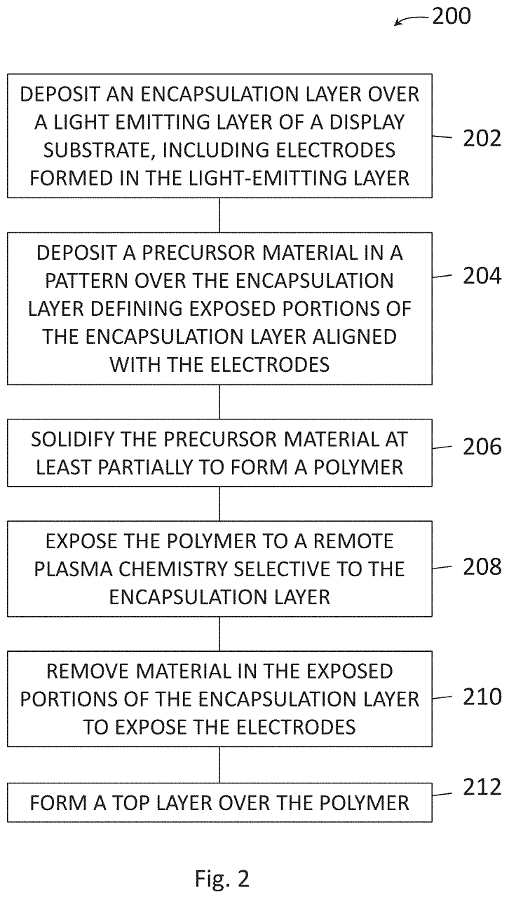

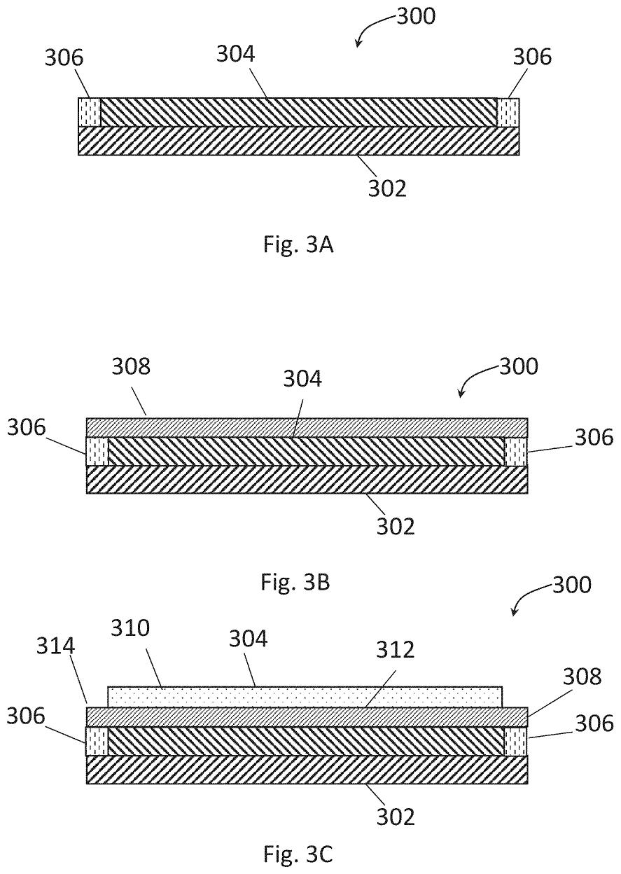

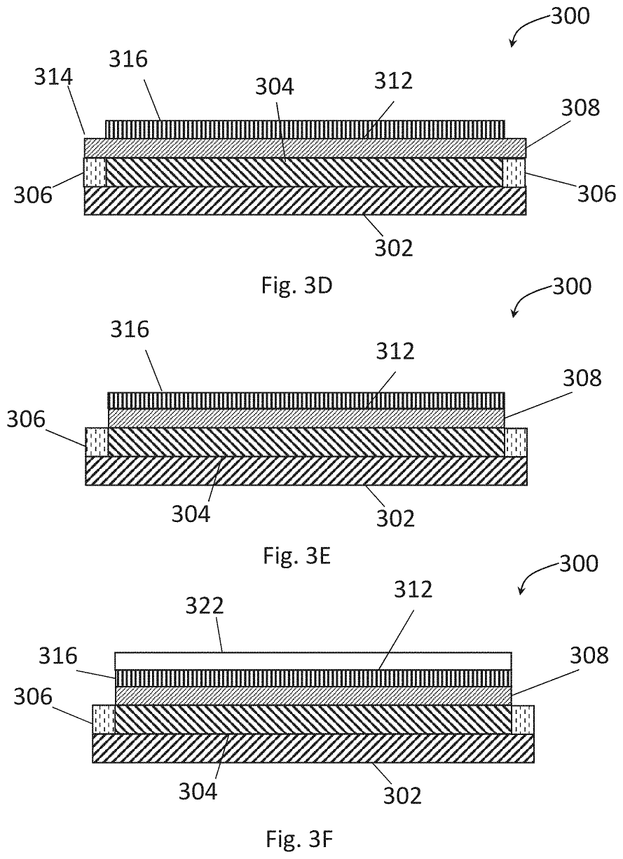

The method 100 can be used to pattern dielectric materials in display substrates and devices. FIG. 2 is a flow diagram summarizing a method 200 according to another embodiment. The description of the method 200 will be accompanied by references to FIGS. 3A-3G, which are schematic cross-sectional views of a display substrate at various stages of the method 200. The method 200 describes how a polymer material can be used as a mask in processing a display device.

At 202, a substrate having a light-emitting layer with electrodes formed in the light-emitting layer is subjected to a deposition process to form an encapsulation layer over the surface of the light-emitting layer. The light-emitting layer may be any light-emitting structure suitable for use in display devices, including OLED layers. Such a substrate 300, having a light-emitting layer 304 formed on a base 302, is shown in FIG. 3A. Electrical contacts 306 are shown in an edge region of the substrate 300.

The encapsulation layer is typically a dielectric material such as silicon nitride. A silicon nitride layer can be coated with silicon oxide, silicon oxynitride, or any crystalline mixture of silicon, oxygen, and nitrogen. FIG. 3B shows the substrate 300 with an encapsulation layer 308 formed over the light-emitting layer 304, including the electrodes 306. The encapsulation layer 308 is used to protect the light-emitting elements of the light-emitting layer 304 and the electrodes 306 from environmental damage. The encapsulation layer 308 has a thickness from about 100 nm to about 100 μm and can be formed by any suitable deposition process. Where the substrate includes temperature sensitive components, such as OLED components, the deposition process for depositing the encapsulation layer 308 may be a low-temperature process, such as PECVD. The encapsulation layer 308 is blanket deposited here over the entire substrate surface.

At 204, a precursor material is deposited on the encapsulation layer. The precursor material includes a polymerization precursor material that, when solidified, forms a polymer. FIG. 3C shows the substrate 300 with a precursor material 310 formed over the encapsulation layer 308. The precursor material 310 is formed over a covered portion 312 of the encapsulation layer 308, leaving an exposed portion 314 of the encapsulation layer 308 with no precursor material formed thereon. The precursor material 310 is thus deposited in a pattern, defining the covered portion 312 and the exposed portion 314 of the encapsulation layer 308. The exposed portion 314 is aligned with the electrodes 306 to enable exposing the electrodes by removing material from the exposed portions 314. The precursor material 310 is any of the precursor materials described above in connection with the method 200.

At 206, the precursor material is at least partially solidified to form a polymer material, which may be transparent or light-blocking to any degree. As described above, the precursor material is subjected to a thermal or radiation process that partially or fully solidifies the precursor material to form the polymer layer. FIG. 3D shows the substrate 300 with the precursor material 310 converted to a polymer material 316. In this case, the polymer material 316 is transparent. The transparent polymer material 316 has substantially the same shape as the precursor material 310, so the covered portion 312 and the exposed portion 314 of the encapsulation layer 308 are substantially unchanged. In some cases, the precursor material may shrink slightly as curing progresses.

At 208, the substrate is exposed to a remote plasma chemistry selective to the encapsulation layer. In the case of a silicon-containing encapsulation layer, as described above, the remote plasma chemistry is based on fluorine atoms. As described above in connection with the method 100, the substrate is disposed in a processing chamber of a remote plasma system, a plasma is formed in a plasma chamber of a remote plasma system, and the plasma is flowed into the processing chamber to interact with the substrate. The plasma is formed by coupling energy into a precursor gas comprising NHₓF₃₋ₓ, sulfur fluorides such as SF₆, S₃F₄, S₂F₄, SF₄, SF₃, S₂F₁₀, substituted sulfur fluorides such as SF₅(NF₂) and SF₅(Ph), where Ph is a phenyl group, and CH_{z}F_{4-z}, where x is an integer from 0 to 3, y is an integer from 0 to 6, and z is an integer from 0 to 4. Examples of such materials are NF₃, SF₆, and CF₄. Other fluorine containing species can be included such as F₂ and HF, and non-reactive species such as N₂, H₂, and Ar can also be included. The plasma is formed using any energy usable to form a plasma from such materials, including RF, pulsed RF, DC, pulsed DC, microwave, and UV energy.

At 210, the remote plasma chemistry is reacted with the exposed portion of the encapsulation layer to remove material in the exposed portions. FIG. 3E shows the substrate 300 following treatment with the remote plasma. Material has been removed from the exposed portions 314 of the encapsulation layer 308 to expose the electrodes 306.

At 212, a top layer is formed over the contacts and the polymer layer. In this case, the polymer layer would be transparent. Alternately, a non-transparent polymer layer could be removed prior to forming the top layer, as described above. FIG. 3F shows the substrate 300 with a top layer 322 formed over the polymer layer 316. The top layer 322 can include any number of layers such as color filter layers, polarization layers, switching layers, buffer layers, light conditioning layers, anti-reflection layers, or other optically active or inactive layers. The top layer may also include finishing layers such as glass.

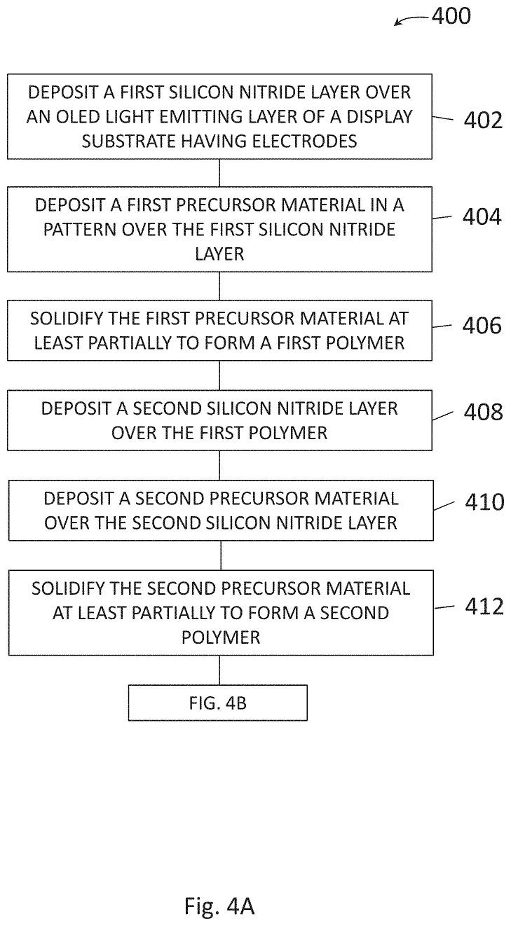

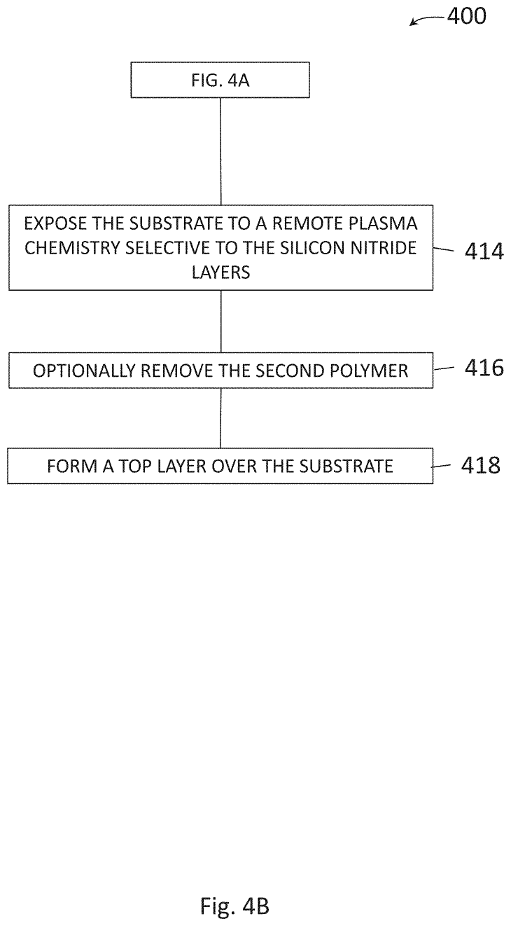

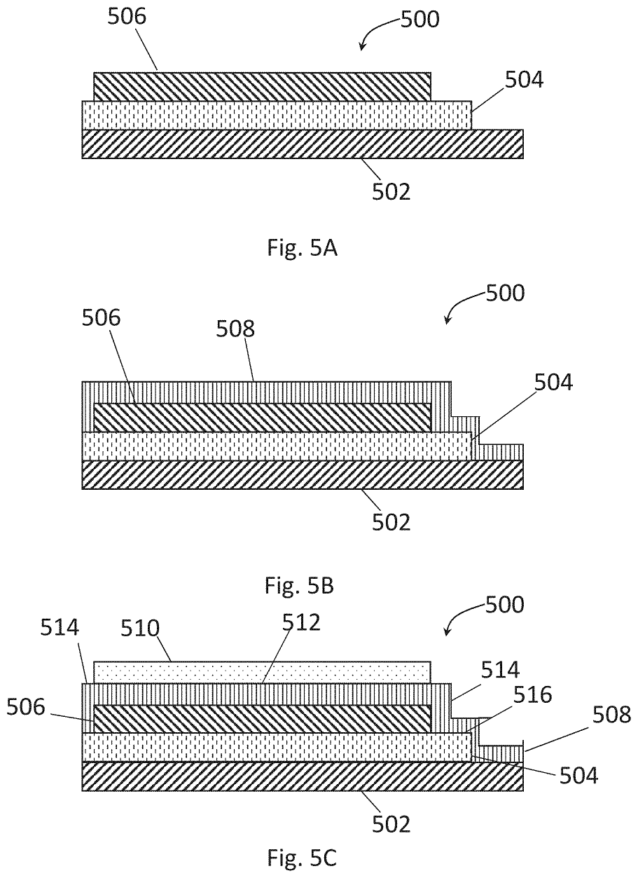

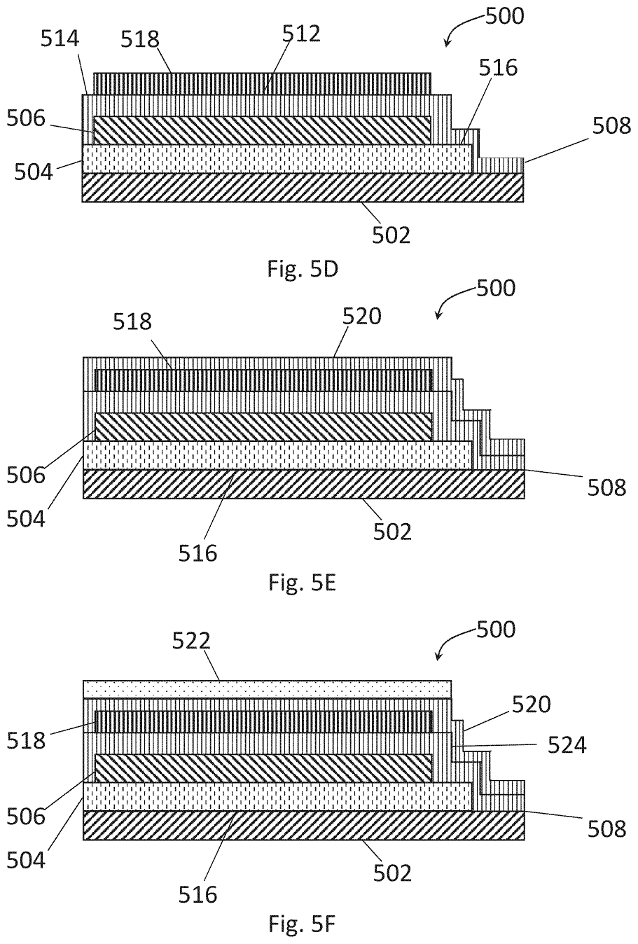

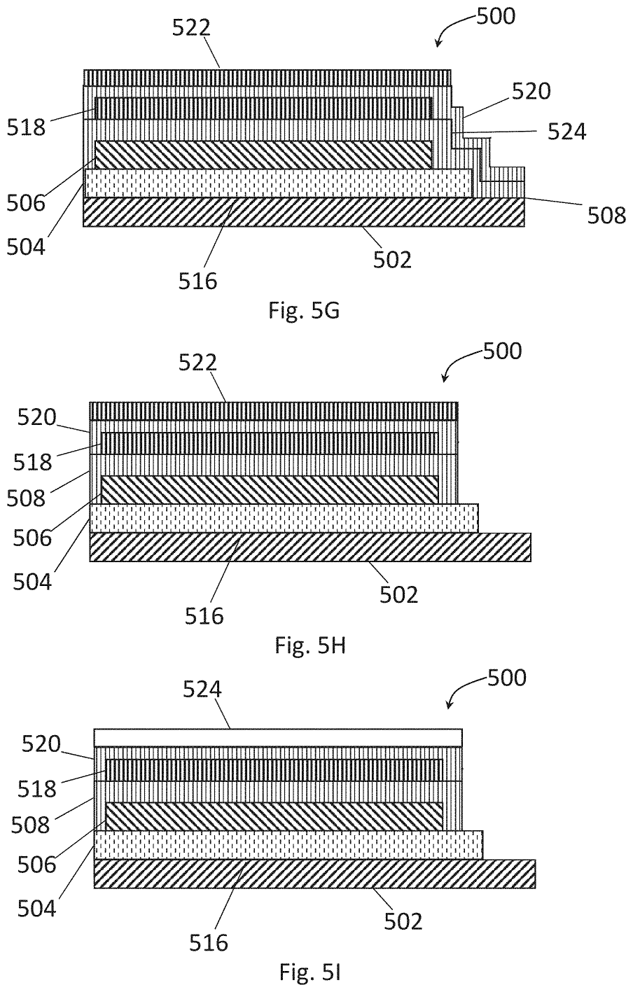

FIG. 4 is a flow diagram summarizing a method 400 according to another embodiment. The description of the method 400 will be accompanied by references to FIGS. 5A-5I, which are schematic cross-sectional views of a display substrate 500 at various stages of the method 400. The method 400 describes how a transparent polymer material can be used as a mask to process an OLED display device.

At 402, a substrate having an OLED light-emitting layer and a layer of electrodes is subjected to a deposition process to form a first silicon nitride layer over the surface of the OLED layer. Such a substrate 500, having an OLED layer 506 formed on a base 502, with electrodes 504, is shown in FIG. 5A. The OLED layer 506 does not cover the entire extent of the electrodes 504 to allow for edge contact to be made.

The silicon nitride layer can be coated with silicon oxide, silicon oxynitride, or any crystalline mixture of silicon, oxygen, and nitrogen. The silicon nitride layer may also be a plurality of silicon nitride layers with different compositions, for example to create a layer with a graded, or quasi-graded, composition of silicon, nitrogen, and oxygen. FIG. 5B shows the substrate 500 with a silicon nitride layer 508 formed over the OLED layer 504 and the contacts 506. The silicon nitride layer 508 is used to protect the contacts 504 and the OLED elements of the OLED layer 506 from environmental damage. The silicon nitride layer 508 is blanket deposited to a thickness from about 10 μm to about 100 μm and can be formed by any suitable deposition process, such as PECVD.

At 404, a first precursor material is deposited on the first silicon nitride layer. The first precursor material includes a polymerization precursor material that, when solidified, forms a polymer. FIG. 5C shows the substrate 500 with a first precursor material 510 formed over the first silicon nitride layer 508. The precursor material 510, which can be any of the precursor materials mentioned above in connection with the method 100, is formed over a covered portion 512 of the silicon nitride layer 508, leaving an exposed portion 514 of the silicon nitride layer 508 with no precursor material formed thereon, similar to the method 200. The exposed portion 514 is aligned with a portion 516 of the electrodes 504 that are not under the OLED layer 506. This portion 516 will eventually be uncovered to allow for making electrical contact.

At 406, the first precursor material is at least partially solidified to form a first polymer. As described above, the first precursor material is subjected to a thermal or radiation process that partially or fully solidifies the first precursor material to form the first polymer. FIG. 5D shows the substrate 500 with the first precursor material 510 converted to a first polymer 518. In this case, the first polymer 518 is transparent.

At 408, a second silicon nitride layer is formed over the first polymer and the exposed portion of the first silicon nitride layer. The second silicon nitride layer can be formed by the same process as the first silicon nitride layer, and may be the same thickness as the first silicon nitride layer or a different thickness. FIG. 5E shows the substrate 500 with a second silicon nitride layer 520 formed over the first polymer 518 and the exposed portions of the first silicon nitride layer 508. The second silicon nitride layer 520 is blanket deposited over the substrate 500, and together with the first silicon nitride layer 508 encapsulates the first polymer 518.

At 410, a second precursor material is deposited over the second silicon nitride layer. The second precursor material may be deposited using the same method as that used to deposit the first precursor material. FIG. 5F shows the substrate 500 with a second precursor material 522 deposited over the second silicon nitride layer 520. Here, the second precursor material 522 is deposited to cover the upper surface of the second silicon nitride layer 520 to cover a vertical portion 524 of the first silicon nitride layer 508 that encapsulates the OLED layer 506. Here, the electrodes 504 extend beyond the vertical portion 524, and the portion of the electrodes 504 extending beyond the vertical portion 524 will eventually be exposed to allow making electrical contact.

At 412, the second precursor material is at least partially solidified to form a second polymer material. The same process used to solidify the first precursor material at least partially can be used.

Referring now to FIG. 4B, at 414 the substrate is exposed to a remote plasma chemistry selective to the silicon nitride layers. The remote plasma chemistry described above in connection with the method 100 can be used. The remote plasma chemistry is reacted with the exposed portion of the silicon nitride layers exposed by the second polymer 522 to remove material in the exposed portion. FIG. 5H shows the substrate 500 following treatment with the remote plasma. Material has been removed from the silicon nitride layers 508 and 520 not beneath the second polymer 522. This results in an exposed portion 524 of the electrodes 504 and a covered portion of the electrodes 504 covered with the OLED layer 506, the first silicon nitride layer 508 encapsulating the OLED layer 506, the first polymer 518 over the first silicon nitride layer 508 and aligned with the OLED layer 506, the second silicon nitride layer 520 encapsulating the first polymer 518 and aligned with the first silicon nitride layer 508, and the second polymer 522 over the second silicon nitride layer 520 and aligned with the second silicon nitride layer 520 and the first silicon nitride layer 508.

At 416, the second polymer may be removed using any of the methods described above to remove the polymer. At 418, a top layer can be formed over the second polymer, or if the second polymer is removed, over the second silicon nitride layer. FIG. 5I shows the substrate 500 with the second polymer removed and a top layer 524 formed over the second silicon nitride layer 520. The method 400 avoids multiple lithography and/or shadow mask deposition steps needed to form the silicon nitride layers with a single etch to remove silicon nitride from two depositions.

While the foregoing is directed to embodiments of the present invention, other and further embodiments of the present disclosure may be devised without departing from the basic scope thereof, and the scope thereof is determined by the claims that follow.

1. A method, comprising:
depositing a patterned polymer precursor by inkjet printing on a substrate comprising a dielectric material;
curing the precursor layer to form a patterned polymer; and
exposing the substrate, with the patterned polymer, to a remote plasma etch chemistry selective to the dielectric material, wherein the remote plasma contains fluorine.

2. (canceled)

3. The method of claim 1, wherein exposing the substrate to the remote plasma comprises:
positioning the substrate in a processing chamber of a remote plasma etch tool;
providing a precursor gas mixture comprising a material selected from the group consisting of NHₓF₃₋ₓ, sulfur fluorides, and CH_{z}F_{4-z}, where x is an integer from 0 to 3, and z is an integer from 0 to 4, to a plasma chamber of the remote plasma etch tool;
forming a plasma from the precursor gas in the plasma chamber; and
flowing the plasma to the processing chamber.

4. The method of claim 3, wherein the precursor gas further comprises F₂, HF, or NH₃.

5. The method of claim 4, wherein the precursor gas further comprises N₂ or Ar.

6. The method of claim 1, further comprising forming a top layer over the patterned polymer layer after exposing the substrate to the remote plasma etch chemistry.

7. The method of claim 1, wherein the polymer of the patterned polymer layer is an acrylate polymer, an epoxy polymer, a styrenic polymer, a silicone polymer, or a combination thereof.

8. The method of claim 1, wherein the substrate is a display substrate.

9. A method, comprising:
forming an encapsulant layer comprising a dielectric material on a display substrate;
inkjet printing a patterned polymer precursor material on the encapsulant layer;
curing the precursor material to form a patterned polymer layer;
and removing a portion of the dielectric material by exposing the dielectric material to a remote plasma containing fluorine using the patterned polymer layer as a mask.

10. The method of claim 9, wherein the dielectric material is a silicon containing material.

11. (canceled)

12. The method of claim 9, wherein exposing the substrate to the remote plasma comprises:
positioning the substrate in a processing chamber of a remote plasma tool;
providing a precursor gas mixture comprising a material selected from the group consisting of NHₓF₃₋ₓ, sulfur fluorides, and CH_{z}F_{4-z}, where x is an integer from 0 to 3, and z is an integer from 0 to 4, to a plasma chamber of the remote plasma etch tool;
forming a plasma from the precursor gas in the plasma chamber; and
flowing the plasma to the processing chamber.

13. The method of claim 9, wherein the patterned polymer layer is transparent.

14. The method of claim 9, wherein the patterned polymer layer is an acrylate polymer, an epoxy polymer, a styrenic polymer, a silicone polymer, or a combination thereof.

15. A method, comprising:
forming a first silicon nitride layer on an OLED display substrate;
forming a polymer layer over the first silicon nitride layer;
forming a second silicon nitride layer over, and encapsulating, the polymer layer;
inkjet printing a patterned polymer precursor layer on a portion of the second silicon nitride layer to define a covered portion and an uncovered portion of the second silicon nitride layer;
curing the precursor layer to form a patterned polymer layer; and
etching the uncovered portion of the first and second silicon nitride layers using a fluorine containing remote plasma and using the patterned polymer layer as an etch mask.

16. The method of claim 9, wherein the patterned polymer layer has a thickness less than about 10 μm.

17. The method of claim 9, further comprising removing the patterned polymer layer.

18. The method of claim 17, further comprising forming a top layer over the second silicon nitride layer.

19. The method of claim 15, wherein the uncovered portion of the second silicon nitride layer corresponds to a portion of the OLED display substrate including electrodes.
